(19) United States
(12) Patent Application Publication
(10) Pub. No.: US 2026/0114160 A1
(43) Pub. Date: Apr. 23, 2026

(54) DISPLAY DEVICE

(71) Applicant: LG Display Co., Ltd., Seoul (KR)

(72) Inventor: Sunggoo JUNG, Paju-si (KR)

(73) Assignee: LG Display Co., Ltd., Seoul (KR)

(21) Appl. No.: 19/260,112

(22) Filed: Jul. 3, 2025

(30) Foreign Application Priority Data
Oct. 21, 2024 (KR) 10-2024-0143628

(51) Int. Cl. H10K 59/80; H10K 59/122

(52) U.S. Cl. CPC H10K 59/878; H10K 59/122; H10K 59/80517; H10K 59/80518

(57) ABSTRACT

Discussed is a display device including a substrate having a subpixel, and the subpixel including an emissive area and a non-emissive area surrounding the emissive area, a reflective electrode on the substrate, an auxiliary layer on the reflective electrode, and an organic light-emitting element on the reflective electrode and the auxiliary layer. The auxiliary layer is disposed in the non-emissive area in the subpixel.

### CROSS-REFERENCE TO RELATED APPLICATION

The present application claims priority to Korean Patent Application No. 10-2024-0143628, filed in the Republic of Korea on Oct. 21, 2024, the entire contents of which is hereby expressly incorporated by reference into the present application.

### BACKGROUND OF THE DISCLOSURE

### Field

This specification relates to a display device.

### Description of the Related Art

With recent advancements in technology and increase in information, there is an increasing demand for display devices that can show images and provide information more easily, and various types of display devices such as liquid crystal display (LCD) devices and organic light emitting diode (OLED) displays are being utilized for such purposes.

Among display devices, OLED displays are self-emissive, offering superior viewing angles and contrast ratios compared to LCDs, while eliminating the need for a separate backlight, enabling a lightweight and slim design with advantageous power consumption. Furthermore, OLED displays support low-voltage DC operation, feature fast response times, and, most notably, offer the advantage of lower manufacturing costs.

Recently, there has been a growing demand for OLED displays that cater to the requirements of augmented reality (AR), virtual reality (VR), and ultra-high-resolution display devices of comparable quality.

### SUMMARY OF THE DISCLOSURE

It is an object of this disclosure to provide a display device capable of improving the color deviation of light emitted through a bank in a non-emissive area.

It is another object of this disclosure to provide a display device capable of improving the color deviation of light emitted through a bank in a non-emissive area by designing the surface height of the light-emitting layer in both the emissive area and the non-emissive area to be identical.

It is another object of this disclosure to provide a display device capable of satisfying microcavity characteristics by adjusting the thickness of the light-emitting layer and the bank.

It is another object of this disclosure to provide a display device capable of satisfying microcavity characteristics by adjusting the thickness of the anode electrode.

It is another object of this disclosure to provide a display device with an improved seam in the encapsulation layer in the non-emissive area.

The objects of this disclosure are not limited to the aforementioned, and other technical objectives can be inferred from the following embodiments.

In order to accomplish the above object, a display device according to an embodiment includes a substrate including an emissive area and a non-emissive area surrounding the emissive area, a reflective electrode on the substrate, an auxiliary layer on the reflective electrode, and an organic light-emitting element on the reflective electrode and the auxiliary layer, wherein the auxiliary layer is disposed in the non-emissive area.

The specific details of other embodiments are included in the detailed description and drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to an embodiment of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view of an organic light emitting element in FIG. 2;

FIG. 5 is a cross-sectional view of a variant of the organic light emitting element in FIG. 2;

FIG. 6 is an enlarged cross-sectional view of Q1 area in FIG. 2;

FIG. 7 is a cross-sectional view of a display device according to another embodiment of the present disclosure;

FIG. 8 is a cross-sectional view of a display device according to another embodiment of the present disclosure;

FIG. 9 is a cross-sectional view of a display device according to another embodiment of the present disclosure;

FIG. 10 is a cross-sectional view of a display device according to another embodiment of the present disclosure;

FIG. 11 is a cross-sectional view of a display device according to another embodiment of the present disclosure;

FIG. 12 is a cross-sectional view of a display device according to another embodiment of the present disclosure;

FIG. 13 is a cross-sectional view of a display device according to another embodiment of the present disclosure; and

FIG. 14 is a cross-sectional view of a display device according to another embodiment of the present disclosure.

### DETAILED DESCRIPTION OF THE EMBODIMENTS

Hereinafter, embodiments of the present disclosure are described with reference to accompanying drawings. In the specification, when a component (or area, layer, part, etc.) is mentioned as being “on top of,” “connected to,” or “coupled to” another component, it means that it can be directly connected/coupled to the other component, or a third component can be placed between them.

The same reference numerals refer to the same components. In addition, in the drawings, the thickness, proportions, and dimensions of the components are exaggerated for effective description of the technical content. The expression “and/or” is taken to include one or more combinations that can be defined by associated components.

The terms “first,” “second,” etc. are used to describe various components, but the components should not be limited by these terms. The terms are used only for distinguishing one component from another component. For example, a first component can be referred to as a second component and, similarly, the second component can be referred to as the first component, without departing from the scope of the embodiments. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof. The term “can” fully encompass all the meanings and coverages of the term “may.” Also, the term “made of” for an element can fully encompass the meaning of being completely formed of the element, or simply including the element.

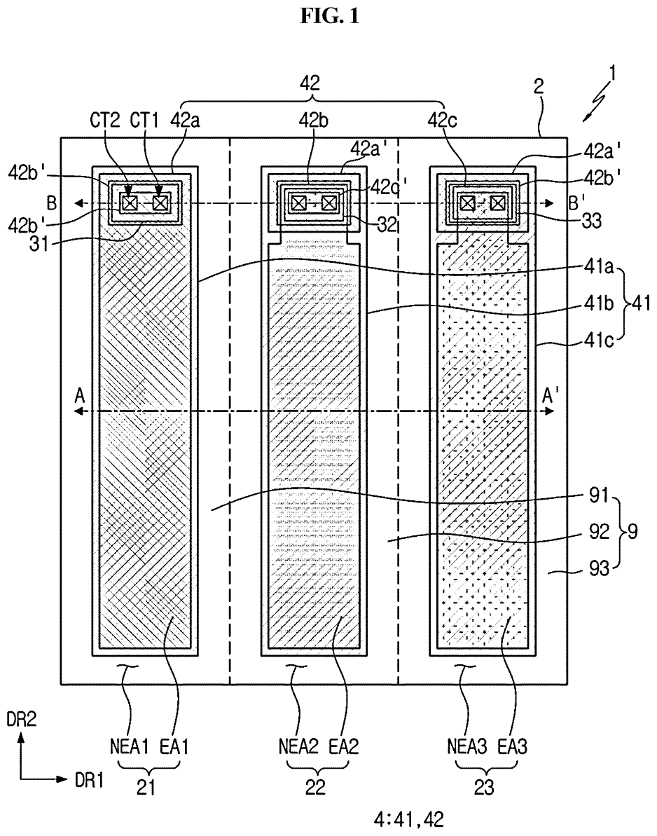

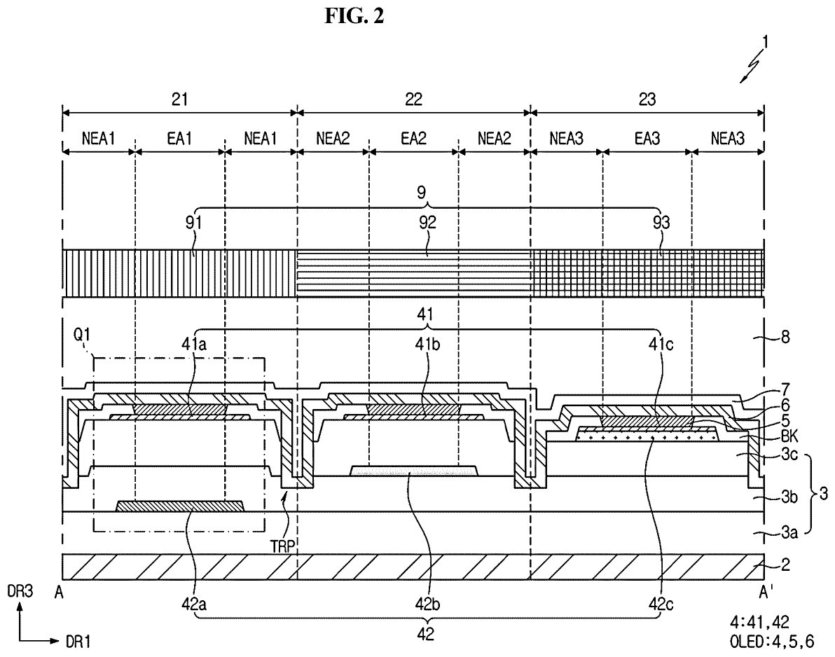

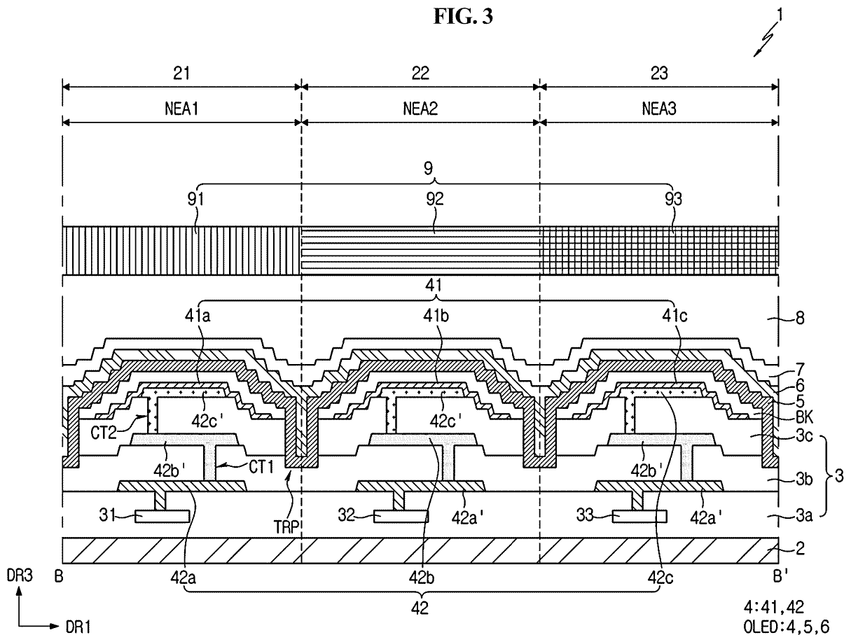

FIG. 1 is a plan view of a display device according to an embodiment. FIG. 2 is a cross-sectional view taken along line A-A′ of FIG. 1; FIG. 3 is a cross-sectional view taken along line B-B′ of FIG. 1; All components of each display device according to all embodiments of the present disclosure are operatively coupled and configured.

Referring to FIGS. 1 to 3, the display device 1 according to an embodiment includes a substrate 2, a first electrode 4, a light-emitting layer 5, and a cathode electrode 6.

A plurality of subpixels 21, 22, and 23 are formed on the substrate 2. The plurality of subpixels 21, 22, and 23 can form a single pixel. A plurality of pixels can be formed on the substrate 2.

The plurality of subpixels 21, 22, and 23 includes the first subpixel 21, the second subpixel 22, and the third subpixel 23. The first subpixel 21, second subpixel 22, and third subpixel 23 are arranged in order, such that one side of the first subpixel 21, for example, the right side, is adjacent to the second subpixel 22, and one side of the second subpixel 22, for example, the right side, is adjacent to the third subpixel 23.

Throughout this disclosure, the phrase “two subpixels are arranged adjacent to each other”should be interpreted to mean that no other subpixel is placed between the two subpixels.

The first subpixel 21 can be configured to emit red (R) light, the second subpixel 22 can be configured to emit green (G) light, and the third subpixel 23 can be configured to emit blue (B) light, although this is not necessarily limited to these colors.

In FIG. 1, the pixel is shown as including only three subpixels 21, 22, and 23, but it is not limited to this configuration, and the pixel can include four subpixels. When the pixel includes four subpixels, a fourth subpixel configured to emit white (W) light can be further included.

The first to third subpixels 21, 22, and 23 can each be provided with the same size, but the embodiments of this disclosure are not limited thereto. For example, the first to third subpixels 21, 22, and 23 can each be configured to have the same width and height. Here, the width can refer to the horizontal direction (first direction DR1) based on FIG. 1, and the height can refer to the direction perpendicular to the width (second direction DR2) based on FIG. 1, though the embodiments of this disclosure are not limited thereto.

Each subpixel 21, 22, and 23 can include an emissive area EA1, EA2, and EA3, and a non-emissive area NEA1, NEA2, and NEA3. The first subpixel 21 can include a first emissive area EA1 and a first non-emissive area NEA1 surrounding the first emissive area EA1, the second subpixel 22 can include a second emissive area EA2 and a second non-emissive area NEA2 surrounding the second emissive area EA2, and the third subpixel 23 can include a third emissive area EA3 and a third non-emissive area NEA3 surrounding the third emissive area EA3. The emissive areas EA1, EA2, and EA3 can be the same as the areas exposed from the bank BK of the anode electrodes 41a, 41b, and 41c, which will be described later.

The first electrode 4 is patterned for each individual panel subpixel 21, 22, and 23. For example, a single first electrode 4 is formed in the first subpixel 21, another first electrode 4 is formed in the second subpixel 22, and yet another first electrode 4 is formed in the third subpixel 23. The first electrode 4 can function as the anode of the display device 1. The first electrode 4 can include a reflective electrode and an anode electrode. The anode electrode 41 and the reflective electrode 42 can be disposed for each subpixel 21, 22, and 23. The anode electrode 41 includes a first anode electrode 41a disposed in the first subpixel 21, a second anode electrode 41b disposed in the second subpixel 22, and a third anode electrode 41c disposed in the third subpixel 23, while the reflective electrode 42 can include a first reflective electrode 42a disposed in the first subpixel 21, a second reflective electrode 42b disposed in the second subpixel 22, and a third reflective electrode 42c disposed in the third subpixel 23. But embodiments of this disclosure are not limited thereto.

A bank BK (FIG. 2), which will be described later, can be disposed on each anode electrode 41a, 41b, and 41c. The bank BK can be configured to cover the edges of the anode electrodes 41a, 41b, and 41c disposed in the first to third subpixels 21, 22, and 23, thereby distinguishing the first subpixel 21, the second subpixel 22, and the third subpixel 23.

The display device 1 includes reflective electrodes 42a, 42b, and 42c with different surface heights for the respective subpixels 21, 22, and 23, thereby further improving light extraction efficiency by utilizing microcavity characteristics.

The microcavity characteristic refers to the phenomenon where, when the distance between the reflective electrodes 42a, 42b, and 42c and the cathode electrode 6 is an integer multiple of half the wavelength (λ/2) of the light emitted from the subpixels 21, 22, and 23, constructive interference occurs, amplifying the light, and the repeated reflection and re-reflection process between the reflective electrodes 42a, 42b, and 42c and the cathode electrode 6 continuously increases the amplification, thereby improving the external light extraction efficiency.

The light-emitting layer 5 can be configured to emit white light. For example, the light-emitting layer 5 can be configured in a two-stack structure including a blue light-emitting layer, a yellow-green light-emitting layer, and a charge generation layer, or in a three-stack structure including a blue light-emitting layer, a green light-emitting layer, a red light-emitting layer, and a charge generation layer to emit white light, but the configuration is not limited to these structures and can also be configured with multiple layers exceeding three stacks or as a single-stack structure, as long as white light can be emitted.

The light-emitting layer 5 according to an embodiment can be individually disposed within the first to third subpixels 21, 22, and 23 and can be formed so as not to be provided as a common layer across the entire first to third subpixels 21, 22, and 23. The light-emitting layer 5 will be described in detail later.

The cathode electrode 6 is configured to form an electric field with the anode electrodes 41a, 41b, and 41c and can function as a cathode. The cathode electrode 6 is disposed on the upper surface of the light-emitting layer 5, opposite to the lower surface where the anode electrodes 41a, 41b, and 41c contact the light-emitting layer 5, and can be provided as a common layer across all of the first to third subpixels 21, 22, and 23.

In the case of a top emission configuration, the cathode electrode 6 can be provided as a second electrode, but in the case of a bottom emission method, it can be provided as a first electrode including a reflective material. In the case of an top emission configuration, the cathode electrode 6 can be formed as a semi-transparent electrode to enhance light extraction efficiency using microcavity characteristics. The display device 1 utilizes microcavity characteristics in the top emission configuration to improve light extraction efficiency, which is why the cathode electrode 6 is formed as a semi-transparent electrode, as an example.

The color filter layer 9 is provided on each of the first to third subpixels 21, 22, and 23 to block predetermined colors from the light emitted by the light-emitting layer 5 of each subpixel 21, 22, and 23. The first color filter 91 provided in the first subpixel 21 can be configured to block all colors except for red (R) light. In this case, the first color filter 91 can be a red color filter. The second color filter 92 provided in the second subpixel 22 can be configured to block all colors except for green (G) light. In this case, the second color filter 92 can be a green color filter. The third color filter 93 provided in the third subpixel 23 can be configured to block all colors except for blue (B) light. In this case, the third color filter 93 can be a blue color filter. However, the embodiments of this disclosure are not limited thereto.

The first to third color filters 91, 92, and 93 provided in each of the first to third subpixels 21, 22, and 23 can be configured to have the same size as the respective subpixels or can be scaled up or down by a certain ratio of the size of each subpixel.

Transistors 31, 32, and 33 can be disposed in the non-emissive areas NEA1, NEA2, and NEA3 of each subpixel 21, 22, and 23, respectively. For example, transistors 31, 32, and 33 can overlap with the reflective electrodes 42a, 42b, and 42c disposed in each subpixel 21, 22, and 23. Transistors 31, 32, and 33 can be electrically connected to the reflective electrodes 42a, 42b, and 42c. But embodiments of this disclosure are not limited thereto.

Hereinafter, a detailed description of the laminated structure of the display device 1 according to an embodiment is provided.

The display device 1 according to an embodiment includes a substrate 2, an insulating layer 3, a first electrode 4, a bank BK, a light-emitting layer 5, a cathode electrode 6, a capping layer 7, an encapsulation layer 8, and a color filter layer 9.

The substrate 2 can be made of a semiconductor material such as silicon, or insulative materials such as a plastic film, a glass substrate, or others.

The substrate 2 can be made of transparent or opaque materials. The first sub-pixel 21, the second sub-pixel 22, and the third sub-pixel 23 are provided on the substrate 2. The first subpixel 21 can emit red (R) light, the second subpixel 22 can emit blue (B) light, and the third subpixel 23 can emit green (G) light.

In an embodiment, the display device 1 can be configured in a so-called top emission method where the emitted light is released or emitted upwards, and therefore, the material of the substrate 100 can be either a transparent material or an opaque material. On the upper side of the first to third subpixels 21, 22, and 23, color filters 91, 92, and 93 can be provided to transmit light of the respective colors as mentioned above.

The insulating layer 3 is formed on the substrate 2. The insulating layer 3 can include an inorganic insulating material. The insulating layer 3 can include a first insulating layer 3a, a second insulating layer 3b on the first insulating layer 3a, and a third insulating layer 3c on the second insulating layer 3b.

The insulating layer 3 includes circuit elements such as a plurality of thin-film transistors 31, 32, and 33 (or CMOS circuits), various signal wiring, and capacitors, which are provided for each subpixel 21, 22, and 23. The first insulating layer 3a can have thin-film transistors 31, 32, and 33 arranged therein. The signal lines can include gate lines, data lines, power lines, and reference lines, and the thin-film transistors 31, 32, and 33 can include switching thin-film transistors, driving thin-film transistors, and sensing thin-film transistors. Each of the subpixels 21, 22, and 23 can be defined by the intersection structure of the gate lines and data lines. The insulating layer 3 can surround the thin-film transistors 31, 32, and 33.

The switching thin-film transistor switches according to the gate signal supplied to the gate line to supply the data voltage from the data line to the driving thin-film transistor.

The driving thin-film transistor switches according to the data voltage supplied from the switching thin-film transistor, generating data current from the power supplied through the power line, which is then supplied to the first electrode 4.

The sensing thin-film transistor senses the threshold voltage variation of the driving thin-film transistor, which causes image quality degradation, and in response to the sensing control signal supplied from the gate line or a separate sensing line, it supplies the current from the driving thin-film transistor to the reference line.

The capacitor serves to maintain the data voltage supplied to the driving thin-film transistor for one frame and is connected to the gate terminal and source terminal of the driving thin-film transistor, respectively.

The first thin-film transistor 31, the second thin-film transistor 32, and the third thin-film transistor 33 are arranged in the first insulating layer 3a for each individual subpixel 21, 22, and 23. The first thin-film transistor 31 is connected to the first electrode 4 disposed on the first subpixel 21 and can apply a driving voltage to emit light of the color corresponding to the first subpixel 21. The first thin-film transistor 31, second thin-film transistor 32, and third thin-film transistor 33 can be located in the same thin-film transistor layer, but the embodiments in this disclosure are not limited to this.

The second thin-film transistor 32 is connected to the first electrode 4 disposed on the second subpixel 22 and can apply a driving voltage to emit light of the color corresponding to the second subpixel 22.

The third thin-film transistor 33 is connected to the first electrode 4 disposed on the third subpixel 23 and can apply a driving voltage to emit light of the color corresponding to the third subpixel 23.

The first subpixel 21, second subpixel 22, and third subpixel 23 each supply a predetermined current to the light-emitting layer according to the data voltage of the data line when a gate signal is input from the gate line, using their respective transistors 31, 32, and 33. As a result, the light-emitting layers of the first subpixel 21, second subpixel 22, and third subpixel 23 can emit light at a predetermined brightness according to the supplied current.

The insulating layer 3 can protect the transistors 31, 32, and 33. The insulating layer 3 can be made of an inorganic insulating material, but it is not limited to this, and can also be made of an organic insulating material. For example, the insulating layer 3 can be made of an inorganic material such as silicon nitride (SiNx), silicon oxide (SiOx), or aluminum oxide (Al₂O₃), but the embodiments in this disclosure are not limited to these materials. The first insulating layer 3a, the second insulating layer 3b, and the third insulating layer 3c can be made of inorganic materials such as silicon nitride (SiNx), silicon oxide (SiOx), or aluminum oxide (Al₂O₃), but the embodiments of this disclosure are not limited thereto.

A plurality of reflective electrode layers can be arranged on the insulating layer 3. The reflective electrode layers can include a first reflective electrode layer on the first insulating layer 3a, a second reflective electrode layer on the second insulating layer 3b, and a third reflective electrode layer on the third insulating layer 3c. The first reflective electrode layer can include the first reflective electrode 42a and the first connection electrode 42a′, the second reflective electrode layer can include the second reflective electrode 42b and the second connection electrode 42b′, and the third reflective electrode layer can include the third reflective electrode 42c and the third connection electrode 42c′. The first reflective electrode 42a and the first connection electrode 42a′ can be disposed in the same layer and include the same material. The second reflective electrode 42b and the second connection electrode 42b′ can be disposed in the same layer and include the same material. The third reflective electrode 42c and the third connection electrode 42c′ can be arranged in the same layer and can include the same material.

Each reflective electrode layer can include a reflective material to reflect light. For example, the reflective material can be metal, but it is not limited to this, and any other material capable of reflecting light can also be used. For example, the reflective material can include aluminum (Al) or silver (Ag), but the embodiments in this disclosure are not limited to these.

The reflective electrode 42 is disposed at a relatively lower position than the light-emitting layer 5, thereby reflecting the light emitted from the light-emitting layer 5 upwards. Here, the upward direction refers to the direction in which the user perceives the light, which may, for example, be the side where the encapsulation layer 8 or the color filter layer 9 is disposed. As a result, the first subpixel 21, second subpixel 22, and third subpixel 23 can achieve higher light efficiency compared to when the reflective electrode 42 is not present, and the user can perceive a high luminance, i.e., a sharper image, through the improved light efficiency. But embodiments of this disclosure are not limited thereto.

The first reflective electrode 42a can be disposed on the first insulating layer 3a in the first emissive area EA1 and the first non-emissive area NEA1 of the first subpixel 21, the second reflective electrode 42b can be disposed on the first insulating layer 3a in the second emissive area EA2 and the second non-emissive area NEA2 of the second subpixel 22, and the third reflective electrode 42c can be disposed on the first insulating layer 3a in the third emissive area EA3 and the third non-emissive area NEA3 of the third subpixel 23. In each non-emissive area NEA1, NEA2, and NEA3, the first reflective electrode 42a and the first connection electrode 42a′ can be electrically connected to each transistor 31, 32, and 33.

A second insulating layer 3b can be disposed over the first reflective electrode 42a and the first connection electrode 42a′. The second insulating layer 3b can reflect the step difference caused by the thickness of the first reflective electrode 42a and the first connection electrode 42a′.

The second reflective electrode 42b and the second connection electrode 42b′ can be disposed on top of the second insulating layer 3b. The second reflective electrode 42b can be disposed in the second subpixel 22, and the second connection electrode 42b′ can be disposed in the first and third subpixels 21 and 23, respectively. The second reflective electrode 42b can be connected to the first connection electrode 42a′ in the second non-emissive area NEA2 of the second subpixel 22 via a first contact hole CT1. The second connection electrode 42b′ can be connected to the first reflective electrode 42a and the first connection electrode 42a′ in the non-emissive areas NEA1 and NEA3 via the first contact hole CT1.

A third insulating layer 3c can be disposed over the second reflective electrode 42b and the second connection electrode 42b′. The third insulating layer 3c can reflect the step difference caused by the thickness of the second reflective electrode 42b and the second connection electrode 42b′.

The third reflective electrode 42c and the third connection electrode 42c′ can be disposed on top of the third insulating layer 3c. The third reflective electrode 42c can be disposed in the third subpixel 23, and the third connection electrode 42c′ can be disposed in the first and second subpixels 21 and 22, respectively. The third reflective electrode 42c can be connected to the second connection electrode 42b′ in the third non-emissive area NEA3 of the third subpixel 23 via a second contact hole CT2. The third connection electrode 42c′ can be connected to the second connection electrode 42b′ and the second reflective electrode 42b in the non-emissive areas NEA1 and NEA2 via the second contact hole CT2.

A trench portion TRP can be formed in the insulating layer 3. For example, the trench portion TRP can be formed in the non-emissive areas NEA1, NEA2, and NEA3. As shown in FIG. 2 and FIG. 3, the trench portion TRP can be formed by penetrating parts of the third insulating layer 3c and the second insulating layer 3b, but the embodiments of this disclosure are not limited to this. In the display device 1 according to an embodiment, the formation of a trench portion TRP between adjacent subpixels 21, 22, and 23 helps reduce lateral leakage current (LLC) caused by the light-emitting layer 5 between these subpixels. But embodiments of this disclosure are not limited thereto.

As shown in FIG. 2, in the emission areas EA1, EA2, and EA3, the distance between the reflective electrodes 42a, 42b, and 42c and the cathode electrode 6 can differ from each other. For example, the distance between the first reflective electrode 42a and the cathode electrode 6 can be the largest, followed by the distance between the second reflective electrode 42b and the cathode electrode 6, with the distance between the third reflective electrode 42c and the cathode electrode 6 being the smallest. But embodiments of this disclosure are not limited thereto.

In this way, the reflective electrodes 42a, 42b, and 42c are formed at various distances (or resonant distances) from the cathode electrode 6 because, depending on the spacing, the reflection and re-reflection between the reflective electrodes 42a, 42b, 42c and the cathode electrode 6 can enhance the light extraction efficiency of different colors of light. Therefore, in the first subpixel 21, the light extraction efficiency for red light can be enhanced, in the second subpixel 22, the light extraction efficiency for green light can be enhanced, and in the third subpixel 23, the light extraction efficiency for blue light can be enhanced.

The anode electrode 41 can include the first anode electrode 41a of the first subpixel 21, the second anode electrode 41b of the second subpixel 22, and the third anode electrode 41c of the third subpixel 23. The anode electrodes 41a, 41b, and 41c are disposed in the anode electrode layer, placed in the same layer, and can include the same material.

In the third emissive area EA3 of the third subpixel 23, the third anode electrode 41c can be directly disposed on the third reflective electrode 42c. In each non-emissive area NEA1, NEA2, and NEA3 of the first to third subpixels 21, 22, and 23, the anode electrodes 41a, 41b, and 41c can be directly disposed on the third connection electrode 42c′ and the third reflective electrode 42c.

Each of the anode electrodes 41a, 41b, and 41c can be electrically connected with the thin-film transistors 31, 32, and 33 in each non-emissive area NEA1, NEA2, and NEA3.

The anode electrodes 41a, 41b, and 41c can include materials with high light transmittance. For example, the anode electrodes 41a, 41b, and 41c can include ITO, IZO, or TiN, but are not limited thereto.

A bank BK can be disposed on the anode electrodes 41a, 41b, and 41c. The bank BK can be made of inorganic materials such as silicon nitride (SiNx), silicon oxide (SiOx), or aluminum oxide (Al₂O₃), but the embodiments in this disclosure are not limited to these materials. The bank BK can be disposed on the non-emissive areas NEA1, NEA2, and NEA3.

In the emissive areas EA1, EA2, and EA3, the bank BK can expose the upper surface of the anode electrodes 41a, 41b, and 41c to define the emissive areas EA1, EA2, and EA3. As shown in FIG. 2, the bank BK can be in contact with the upper surface and the side surface of the anode electrodes 41a, 41b, and 41c. As shown in FIG. 3, in the non-emissive areas NEA1, NEA2, NEA3, the bank BK can cover the entire upper surface of the anode electrodes 41a, 41b, and 41c, but the embodiments of the present disclosure are not limited thereto.

With reference to FIG. 2, one portion of the bank BK can be disposed on the upper surface and the side surface of anode electrodes 41a, 41b, and 41c and another portion of the bank BK can be disposed on an upper surface of the insulating layer 3. For example, the another portion of the bank BK can be disposed on an upper surface of the third insulating layer 3c. In various embodiments of the present disclosure, the another portion of the bank BK can extend from the one portion of the bank BK to the trench portion TRP formed in the insulating layer 3. A step can be located between the first portion and the second portion of the bank BK based on a change of height from the anode electrodes 41a, 41b, and 41c to the upper surface of the insulating layer 3, but embodiments of the present disclosure are not limited thereto, and the another portion of the bank BK can be formed to have a surface height that is the same or coplanar with a surface height of the one portion of the bank. In various embodiments of the present disclosure, a thickness of the one portion of the bank BK can be the same or different from a thickness of the another portion of the bank BK.

With reference to FIG. 2, the thickness of the one portion of the bank BK can be equal or approximately equal as a thickness of the light emitting layer 5, but embodiments of the present disclosure are not limited thereto. In other embodiments of the present disclosure, a thickness of the one portion of the bank BK and/or the thickness of the another portion of the bank BK can be different from the thickness of the light emitting layer 5. For example, the thickness of the one portion of the bank BK and/or the thickness of the another portion of the bank BK can be greater than the thickness of the light emitting layer 5. When greater, the thickness of the one portion of the bank BK and/or the thickness of the another portion of the bank BK can be equal or approximately equal to a combined thickness of the light emitting layer 5 and an underlying anode electrodes 41a, 41b, and 41c.

With reference to FIG. 2, the one portion of the bank BK can be disposed to cover the edge of the anode electrodes 41a, 41b, and 41c, but embodiments of the present disclosure are not limited thereto. an edge of the light emitting layer 5 and the edge of the anode electrodes 41a, 41b, and 41c can be aligned or coincide. When the edge of the light emitting layer 5 and the edge of the anode electrodes 41a, 41b, and 41c are aligned or coincide, a lateral edge of the bank BK can contact both the edge of the light emitting layer 5 and the edge of the anode electrodes 41a, 41b, and 41c.

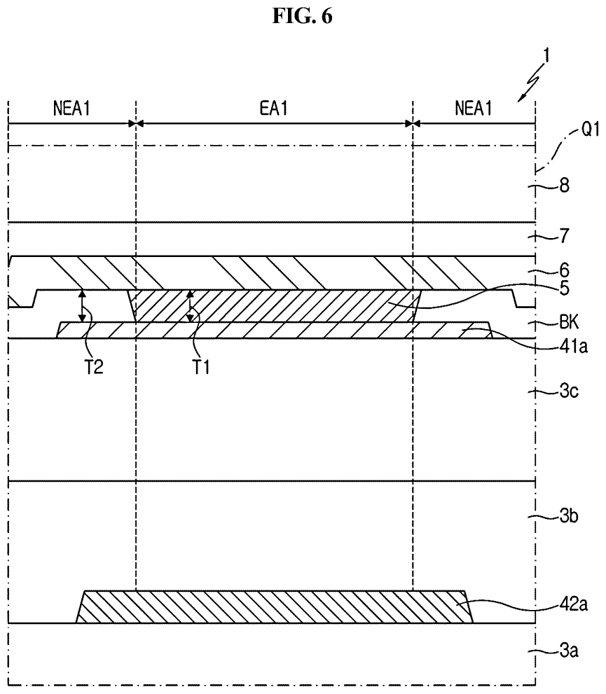

The light-emitting layer 5 can be disposed on the anode electrodes 41a, 41b, and 41c. The light-emitting layer 5 can be disposed within the emissive areas EA1, EA2, and EA3. The light-emitting layer 5 can directly contact the sides of the bank BK in adjacent non-emissive areas NEA1, NEA2, and NEA3, but need not contact the upper surface of the bank BK. The surface height of the light-emitting layer 5 can be the same as the surface height of the adjacent bank BK, but the embodiments of this disclosure are not limited thereto. The light-emitting layer 5 and the bank BK will be discussed in detail later with reference to FIG. 6.

The organic light-emitting element OLED according to an embodiment can include a first electrode 4 (ANO), a cathode electrode 6 (CAT), and a light-emitting layer 5 between the first electrode 4 and the cathode electrode 6.

The light-emitting layer 5 can be configured to emit white (W) light. To achieve this, the light-emitting layer 5 can be formed of a plurality of stacks that emit light of different colors. Specifically, the light-emitting layer 5 can include a first stack, a second stack, and a charge generation layer (CGL) provided between the first and second stacks.

The cathode electrode 6 is formed on the light-emitting layer 5. The cathode electrode 6 can function as the cathode of the display device 1. The cathode electrode 6 is formed in each subpixel 21, 22, and 23, as well as between the subpixels.

In an embodiment, the display device 1 can have a cathode electrode 6 made of a semi-transparent electrode to implement white light with high light efficiency in the top emission configuration. As a result, micro cavity effects can be obtained for each of the first to third subpixels 21, 22, and 23. The micro cavity effect can be achieved by repeated reflection and re-reflection of light between the cathode electrode 6 and the reflective electrode 42, which improves light extraction efficiency.

Meanwhile, the cathode electrode 6 is formed on the upper surface of the light-emitting layer 5, and can be formed along the profile of the light-emitting layer 5. Since the light-emitting layer 5 is formed along the profile of the first electrode 4 in the emissive area, the cathode electrode 6 can consequently be formed along the profile of the first electrode 4. Additionally, the capping layer 7 on the cathode electrode 6 can also be formed to follow the profile of the cathode electrode 6.

The capping layer 7 can be made of an inorganic insulating material, but is not limited thereto. The capping layer 7 can be disposed on the cathode electrode 6 to protect the organic light-emitting device (OLED).

The encapsulation layer 8 is formed on the cathode electrode 6 and serves to prevent external moisture from penetrating into the light-emitting layer 5. This encapsulation layer 8 can be made of an inorganic insulating material or can be formed in an alternating stack structure of inorganic and organic insulating materials, but is not limited to these configurations.

The color filter layer 9 is formed on the encapsulation layer 8. The color filter layer 9 can include a first color filter 91 of red (R) provided in the first subpixel 21, a second color filter 92 of green (G) provided in the second subpixel 22, and a third color filter 93 of blue (B) provided in the third subpixel 23, but is not limited to these configurations.

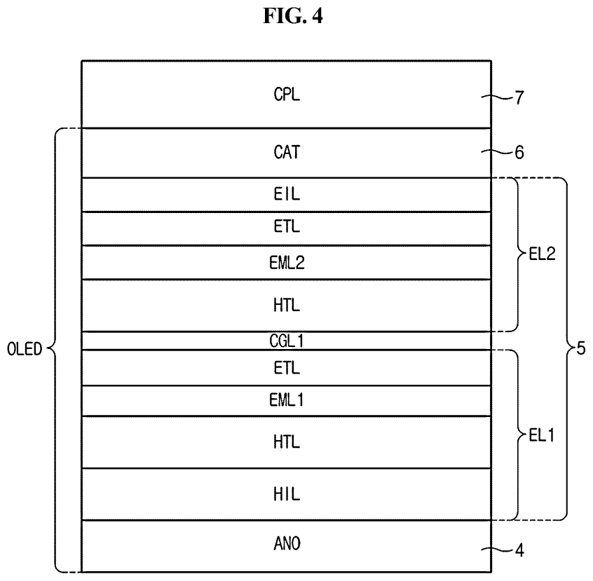

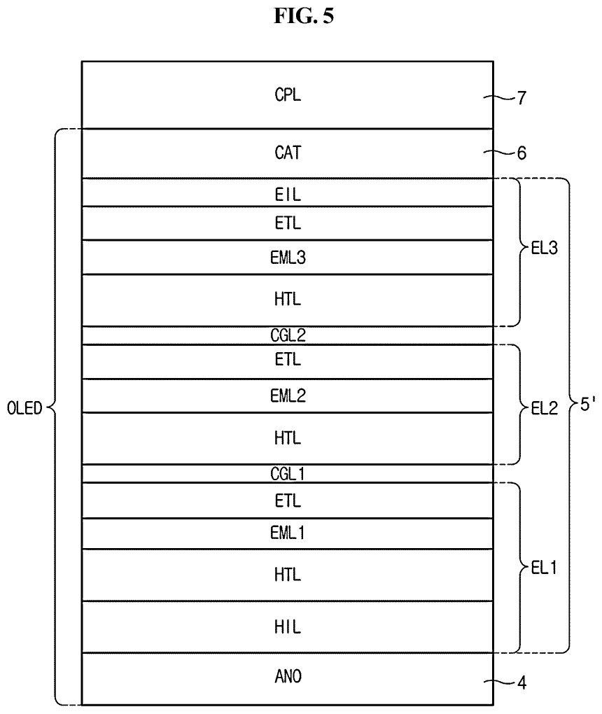

FIG. 4 is a cross-sectional view of an organic light emitting element in FIG. 2. FIG. 5 is a cross-sectional view of a variant of the organic light emitting element in FIG. 2.

Referring to FIGS. 1 to 4, the light-emitting layer 5 can include a first stack EL1, a second stack EL2, and a first charge generation layer CGL1 provided on the first electrode 4.

The first stack EL1 is provided on the first electrode 4 and can have a structure where a hole injecting layer HIL, a hole transporting layer HTL, a first emitting layer EML1 such as a blue (B) emitting layer, and an electron transporting layer ETL are sequentially stacked.

The first stack EL1 can be disposed between the first subpixel 21 and the second subpixel 22, as well as between the second subpixel 22 and the third subpixel 23.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a second emitting layer EML2 such as a yellow-green (YG) emitting layer, an electron transporting layer ETL, and an electron injecting layer EIL are sequentially stacked.

The second stack EL2 can be disposed between the first subpixel 21 and the second subpixel 22, as well as between the second subpixel 22 and the third subpixel 23.

As a result, the light-emitting layer 5 can be provided as a common layer across the entire first to third subpixels 21, 22, and 23, as shown in FIGS. 2 and 3.

As shown in FIG. 5, the light-emitting layer 5′of the organic light-emitting element OLED according to an embodiment can include a first stack EL1, a second stack EL2, a third stack EL3, a first charge generation layer CGL1 between the first stack EL1 and the second stack EL2, and a second charge generation layer CGL2 between the second stack EL2 and the third stack EL3, provided on the first electrode 4.

The first stack EL1 is provided on the first electrode 4 and can have a structure where a hole injecting layer HIL, a hole transporting layer HTL, a blue (B) emitting layer EML1, and an electron transporting layer ETL are sequentially stacked.

The first stack EL1 can be disposed between the first subpixel 21 and the second subpixel 22, as well as between the second subpixel 22 and the third subpixel 23, for example, on the bank BK. But embodiments of this disclosure are not limited thereto.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a green (G) emitting layer EML2, and an electron transporting layer ETL are sequentially stacked.

The second stack EL2 can be disposed between the first subpixel 21 and the second subpixel 22, as well as between the second subpixel 22 and the third subpixel 23, i.e., on the bank BK.

The second charge generation layer CGL2 serves to supply charge to the second stack EL2 and the third stack EL3. The second charge generation layer CGL2 can include an N-type charge generation layer to supply electrons to the second stack EL2 and a P-type charge generation layer to supply holes to the third stack EL3. The N-type charge generation layer can be made by doping a metal material.

The third stack EL3 is provided on the second stack EL2 and can have a structure where a hole transporting layer HTL, a red (R) emitting layer EML3, an electron transporting layer ETL, and an electron injecting layer EIL are sequentially stacked.

As shown in FIGS. 1 to 5, the charge generation layer CGL1, CGL2 can be disposed between the first subpixel 21 and the second subpixel 22, and between the second subpixel 22 and the third subpixel 23. Meanwhile, in the display device 1 according to an embodiment, since the light-emitting layer 5 is disposed between each of the subpixels 21, 22, and 23, when one subpixel emits light, lateral leakage current can occur through the charge generation layers CGL1 and CGL2 into adjacent subpixels 21, 22, and 23. However, a trench portion TRP can be formed between the subpixels 21, 22, and 23. Through the trench portion TRP, the formation length of the light-emitting layer 5 at the boundary of the subpixels 21, 22, and 23 can be extended, resulting in a longer current path. As a result, side leakage current can be prevented. Furthermore, by separating the common light-emitting layer 5 in the trench portion TRP, side leakage current can be prevented in advance.

Referring again to FIGS. 2 and 3, the cathode electrode 6 is formed on the light-emitting layer 5, the encapsulation layer 8 is formed on the cathode electrode 6, and the color filter layer 9 is formed on the encapsulation layer 8.

A black matrix can be provided between the first to third color filters 91, 92, and 93 to prevent color mixing between subpixels.

FIG. 6 is an enlarged cross-sectional view of Q1 area in FIG. 2.

Referring to FIGS. 2 and 6, according to an embodiment of the display device 1, the thickness T1 of the light-emitting layer 5 and the thickness T2 of the bank BK can be the same. As a result, the surface height of the bank BK in the first non-emissive area NEA1 and the surface height of the light-emitting layer 5 in the first emissive area EA1 can be the same. In one embodiment, the surface height in the region where the light-emitting layer 5 and the bank BK come into contact with each other can be identical.

The side surface (or outer surface) of the bank BK can have hydrophobic properties. For example, the side surface of the bank BK can be formed of a material that repels the light-emitting layer 5. However, the embodiments of this disclosure are not limited to this, and the bank BK itself can include a material that repels the light-emitting layer 5.

The light-emitting layer 5 can be applied onto the bank BK (or inside the bank BK) using an inkjet method, where the bank BK includes a material that repels the light-emitting layer 5. Since the light-emitting layer 5 and the bank BK form a repulsive force, the light-emitting layer 5 does not overflow outside of the bank BK but can be placed within the bank BK. In some embodiments, the surface of the light-emitting layer 5 can have a convex shape in the upward direction. In some embodiments, the light-emitting layer 5 can directly contact the lower part of the inner side surface of the bank BK, while exposing the upper part.

When the light-emitting layer 5 extends to the first non-emissive area NEA1, due to the step formed by the first anode electrode 41a, the surface height of the light-emitting layer 5 in the first non-emissive area NEA1 can be higher than that in the first emissive area EA1. Furthermore, due to the step formed by the first anode electrode 41a, the light-emitting layer 5 can have different thicknesses in the first non-emissive area NEA1 and the first emissive area EA1. For example, when the light-emitting layer 5 has different thicknesses in the first non-emissive area NEA1 and the first emissive area EA1, differences in luminance and color purity (or color mismatch) can occur within the same subpixel across different areas. However, according to the display device 1 of the embodiment, since the light-emitting layer 5 is disposed only in the first emissive area EA1 by the bank BK, the occurrence of luminance and color purity differences can be improved. But embodiments of this disclosure are not limited thereto.

Hereinafter, descriptions of display devices according to other embodiments will be provided. In explaining the following embodiments, detailed descriptions of configurations that are the same as or similar to those described with reference to FIGS. 1 to 6 will be omitted to avoid redundancy.

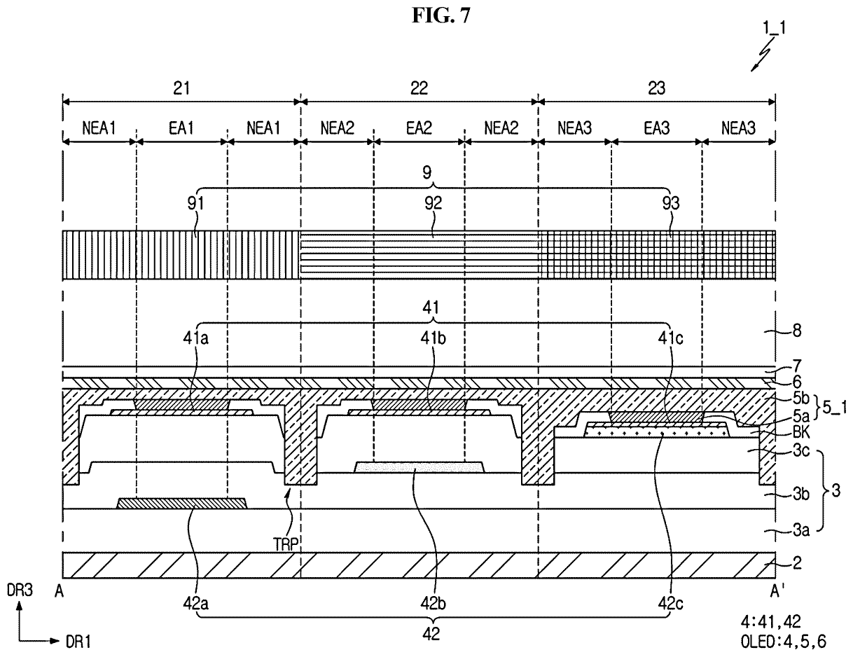

FIG. 7 is a cross-sectional view of a display device according to another embodiment.

Referring to FIG. 7, the light-emitting layer 5_1 of the display device 1_1 according to this embodiment differs from the display device 1 shown in FIG. 2 in that the light-emitting layer can include the first light-emitting layer 5a and the second light-emitting layer 5b disposed on the first light-emitting layer 5a.

More specifically, the first light-emitting layer 5a in FIG. 7 can be disposed in the same region as the light-emitting layer 5 in FIG. 2, and the second light-emitting layer 5b can be disposed across the entire subpixel areas 21, 22, and 23. For example, the second light-emitting layer 5b can extend into the non-emissive areas NEA1, NEA2, and NEA3. But embodiments of this disclosure are not limited thereto.

The first light-emitting layer 5a can include at least one configuration disposed below the first stack EL1, which includes a hole injecting layer HIL, a hole transporting layer HTL, a blue B emitting layer EML1, an electron transporting layer ETL, a first charge generating layer CGL1, a hole transporting layer HTL, a yellow-green YG emitting layer EML2, an electron transporting layer ETL, and an electron injecting layer EIL, as described in FIG. 4. The second light-emitting layer 5b can include the remaining configurations that are not part of the first light-emitting layer 5a. Although this disclosure illustrates the light-emitting layer 5_1 as having two layers, the configuration is not limited thereto, and the light-emitting layer 5_1 can alternatively include three layers. Also, the second light-emitting layer 5b can be disposed in the trench portion TRP.

According to this embodiment, since the first light-emitting layer 5a is disposed to be at the same surface height as the bank BK, the second light-emitting layer 5b, disposed on the first light-emitting layer 5a and the bank BK, can maintain the same surface height in the region overlapping the anode electrodes 41a, 41b, and 41c. For example, the surface height of the second light-emitting layer 5b in the emissive areas EA1, EA2, and EA3 and in the non-emissive areas NEA1, NEA2, and NEA3 can be the same. This can help reduce the occurrence of luminance and color purity differences. But embodiments of this disclosure are not limited thereto.

The additional description that has already been made with reference to FIGS. 1 and 6 will be omitted.

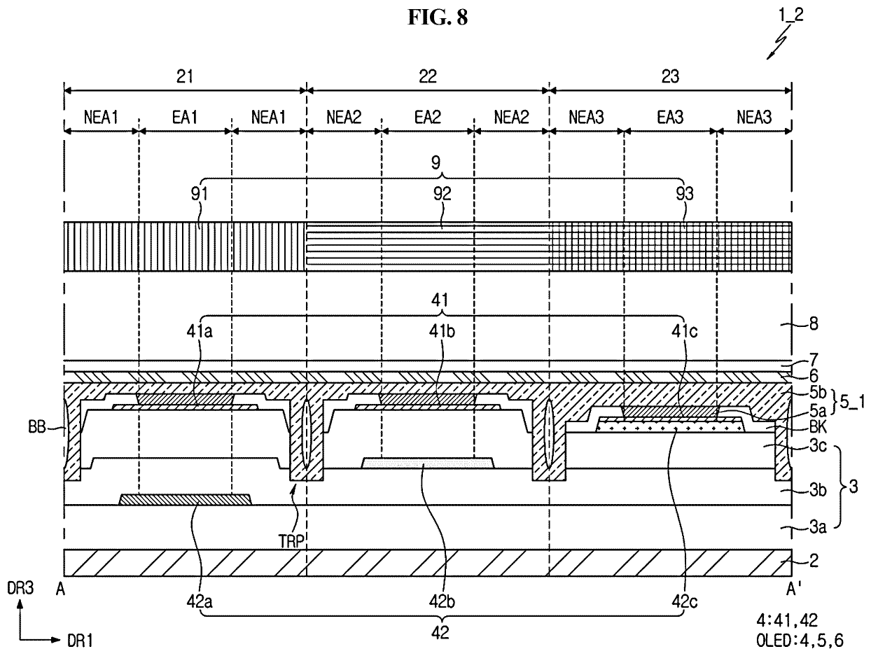

FIG. 8 is a cross-sectional view of a display device according to another embodiment.

Referring to FIG. 8, the display device 1_2 according to this embodiment differs from the display device 1_1 according to FIG. 7 in that the second light-emitting layer 5b has a void BB formed in the non-emissive areas NEA1, NEA2, and NEA3.

More specifically, unlike the first light-emitting layer 5a, the second light-emitting layer 5b is disposed across the entire subpixels 21, 22, and 23, so a void BB can be additionally formed within the second light-emitting layer 5b in the trench portion TRP.

Further details are as described above with reference to FIG. 7 and will be omitted hereinafter.

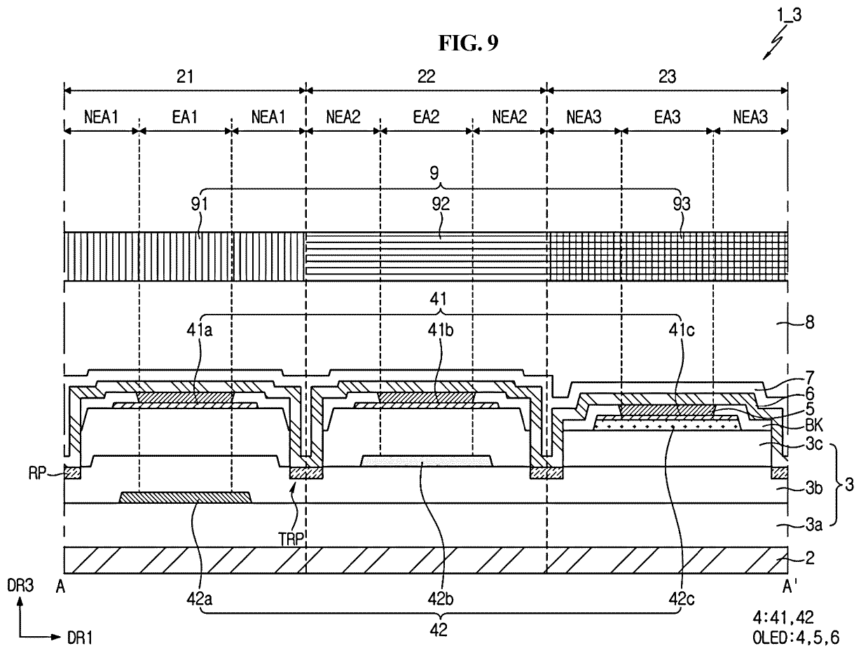

FIG. 9 is a cross-sectional view of a display device according to another embodiment.

Referring to FIG. 9, the display device 1_3 according to this embodiment differs from the display device 1 shown in FIG. 2 in that a residue portion RP is further disposed within the trench portion TRP.

The residue portion RP can include the same material as the light-emitting layer 5. In this embodiment, the light-emitting layer 5 is uniformly applied on a bank BK containing a material that repels the light-emitting layer 5, and after heat treatment, the light-emitting layer 5 can be disposed only within the bank BK. However, during the heat treatment process, some of the light-emitting layer 5 can remain as residue portion RP in the trench portion TRP.

Further details are as described above with reference to FIG. 2 and will be omitted hereinafter.

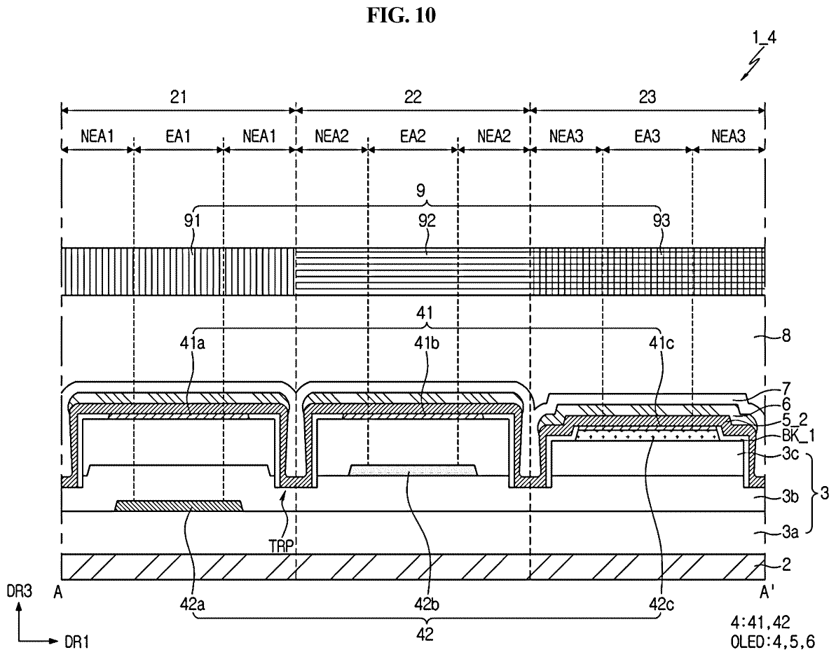

FIG. 10 is a cross-sectional view of a display device according to another embodiment.

Referring to FIG. 10, the display device 1_4 according to this embodiment differs from the display device 1 shown in FIG. 2 in that the surface height of the bank BK_1 and the surface height of the anode electrodes 41a, 41b, and 41c in the emission regions EA1, EA2, and EA3 can be the same.

More specifically, the bank BK_1 disposed in each non-emission region NEA1, NEA2, and NEA3 directly contacts the side surfaces of the adjacent anode electrodes 41a, 41b, and 41c and can have the same surface height as the adjacent anode electrodes 41a, 41b, and 41c. The bank BK_1 disposed in each non-emission region NEA1, NEA2, and NEA3 need not be disposed on the upper surfaces of the adjacent anode electrodes 41a, 41b, and 41c. The bank BK_1 extends into the trench portion TRP and can directly contact the inner side surfaces of the third insulating layer 3c, the inner side surfaces of the second insulating layer 3b, and the upper surface of the first insulating layer 3a in the trench portion TRP.

Therefore, the light-emitting layer 5_2 disposed on the upper surface of the anode electrodes 41a, 41b, and 41c, and the light-emitting layer 5_2 disposed on the upper surface of the bank BK_1 adjacent to the anode electrodes 41a, 41b, and 41c, can have the same surface height. For example, the surface height of the light-emitting layer 5_2 disposed on the upper surface of the anode electrodes 41a, 41b, and 41c and the surface height of the light-emitting layer 5_2 disposed on the upper surface of the bank BK_1 adjacent to the anode electrodes 41a, 41b, and 41c can be the same. Meanwhile, the third anode electrode 41c in FIG. 10 is directly disposed on the upper surface of the third reflective electrode 42c, so the bank BK_1 can directly contact the side surfaces of the third anode electrode 41c and the side surfaces of the third reflective electrode 42c. In some embodiments, the thickness of the bank BK_1 in the third non-emission region NEA3 of the third subpixel 23 can be equal to the sum of the thicknesses of the third anode electrode 41c and the third reflective electrode 42c. But embodiments of this disclosure are not limited thereto.

According to this embodiment, equalizing the light-emitting layer 5_2 disposed on the upper surface of the anode electrodes 41a, 41b, and 41c and the light-emitting layer 5_2 disposed on the upper surface of the bank BK_1 adjacent to the anode electrodes 41a, 41b, and 41c to have the same surface height helps reduce luminance and color purity differences.

Moreover, since the encapsulation layer 8 on top of the light-emitting layer 5_2 is also generally flat in the non-emission regions NEA1, NEA2, and NEA3, the occurrence of seams (or cracks) inside the encapsulation layer 8 in the non-emission regions NEA1, NEA2, and NEA3 can be improved.

With reference to FIG. 10, the bank BK_1 need not include a step in one or more of the first sub subpixel 21, the second subpixel 22 and the third subpixel 23. Also, the bank BK_1 can have a first portion that is disposed on an upper surface of the insulating layer 3, such as the third insulating layer 3c, and a second portion that is on a side surface of the insulation layer 3, such as the third insulation layer 3c. A transition between the first portion and the second portion of the bank BK_1 can be by a corner or a bend, but embodiments of the present disclosure are not limited thereto, and the bank BK_1 need not include the second portion. A length of the first portion and the second portion of the bank BK_1 can be the same or different. For example, the length of the first portion can be longer than the length of the second portion in a cross sectional view. In various embodiments of the present disclosure, the bank BK_1 can be separated between the one or more of the first sub subpixel 21, the second subpixel 22 and the third subpixel 23 at the trench portion TRP but embodiments of the present disclosure are not limited thereto, and the bank BK_1 can be connected between the one or more of the first sub subpixel 21, the second subpixel 22 and the third subpixel 23 at the trench portion TRP.

Further details are as described above with reference to FIG. 2 and will be omitted hereinafter.

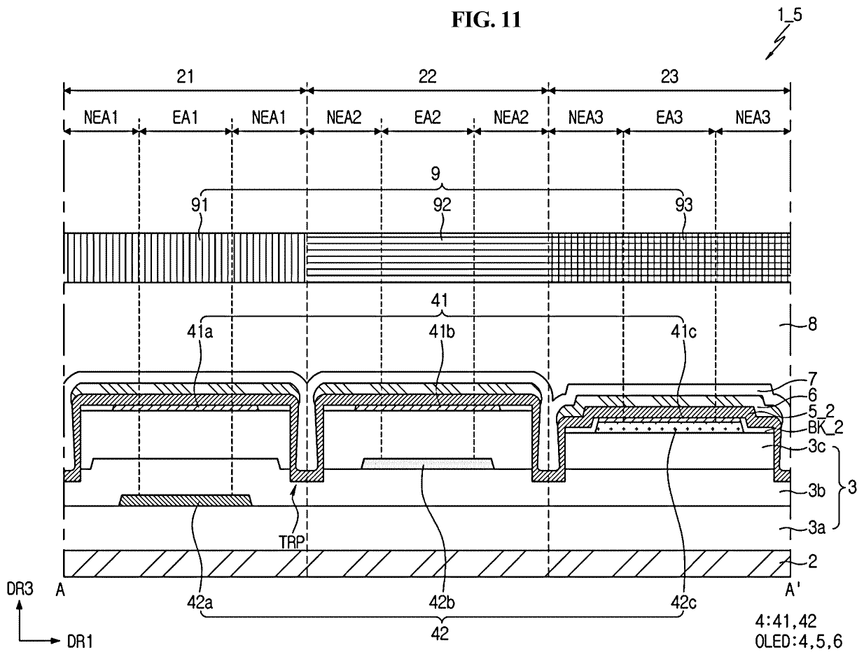

FIG. 11 is a cross-sectional view of a display device according to another embodiment.

Referring to FIG. 11, the display device 1_5 according to this embodiment differs from the display device 1_4 according to FIG. 10 in that the bank BK_2 does not overlap with the trench portion TRP.

Further details are as described above with reference to FIG. 10 and will be omitted hereinafter.

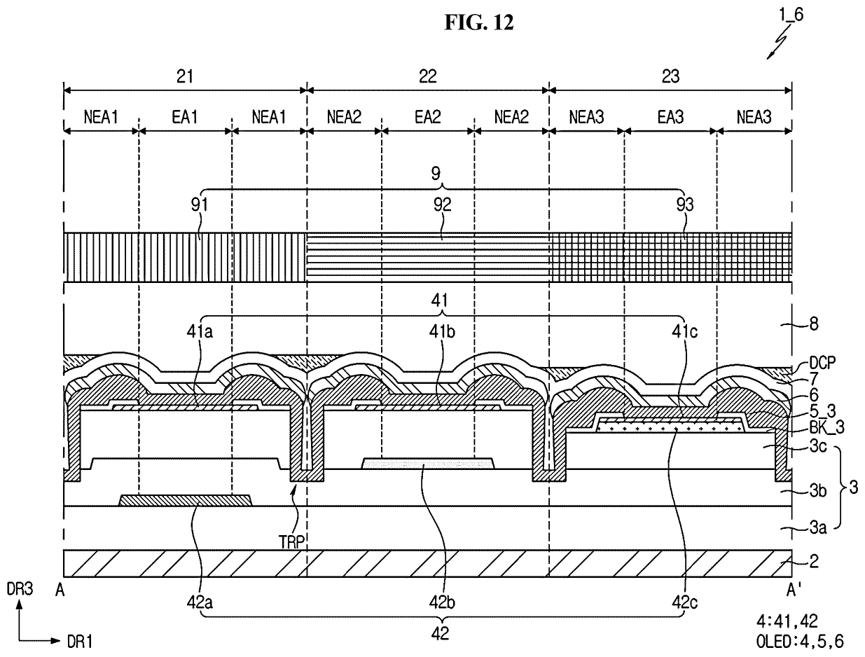

FIG. 12 is a cross-sectional view of a display device according to another embodiment.

Referring to FIG. 12, the display device 1_6 according to this embodiment differs from the display device 1_4 according to FIG. 10 in that the display device 1_6 further includes a step compensation portion DCP between the capping layer 7 and the encapsulation layer 8.

More specifically, the step compensation portion DCP can be disposed in the non-emission regions NEA1, NEA2, and NEA3 and can directly contact the capping layer 7 and the encapsulation layer 8. The step compensation portion DCP can include an organic material to compensate for a step formed under the step compensation portion DCP in the non-emission regions NEA1, NEA2, and NEA3. For example, the step compensation portion DCP can include ink, but the embodiments of this disclosure are not limited thereto. In the non-emission regions NEA1, NEA2, and NEA3, the surface height of the step compensation portion DCP can be the same as the surface height of the capping layer 7, but the embodiments of this disclosure are not limited thereto.

According to this embodiment, the step compensation portion DCP causes the upper encapsulation layer 8 to be disposed generally flat in the non-emission regions NEA1, NEA2, and NEA3, thereby improving the occurrence of seams (or cracks) inside the encapsulation layer 8 in the non-emission regions NEA1, NEA2, and NEA3.

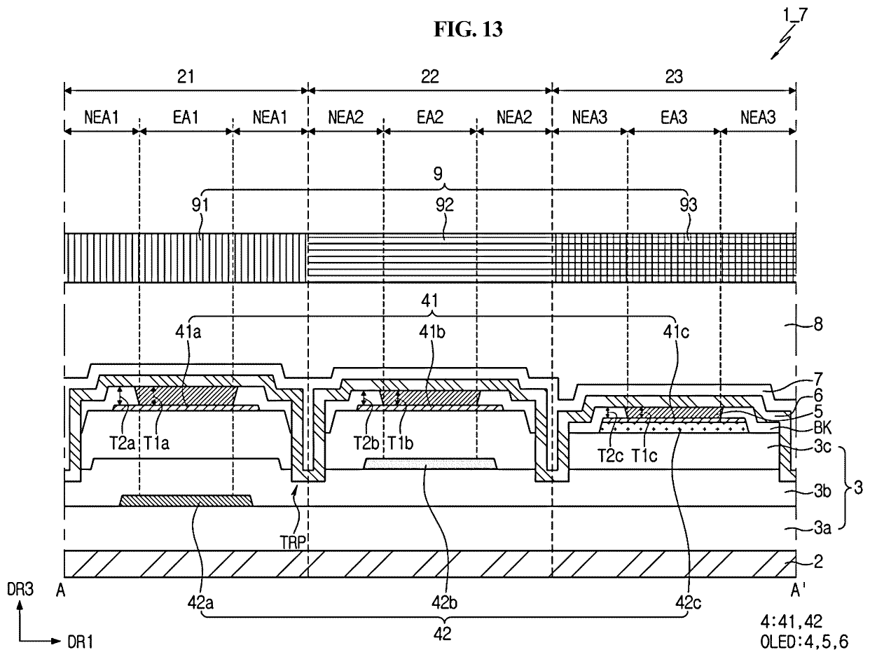

FIG. 13 is a cross-sectional view of a display device according to another embodiment.

Referring to FIG. 13, the display device 1_7 according to this embodiment differs from the display device 1 according to FIG. 2 in that the thicknesses T2a, T2b, and T2c of the bank BK and the thicknesses T1a, T1b, and T1c of the light-emitting layer 5 can be adjusted.

More specifically, in each subpixel 21, 22, and 23, the thicknesses T2a, T2b, of T2c of the bank BK and the thicknesses T1a, T1b, and T1c of the light-emitting layer 5 can be adjusted to differ from each other. For example, the thickness T1a of the first light-emitting layer in the first subpixel 21, the thickness T1b of the first light-emitting layer in the second subpixel 22, and the thickness T1c of the first light-emitting layer in the third subpixel 23 can differ from each other. Similarly, the thicknesses T2a, T2b, and T2c of the banks in the first subpixel 21, the second subpixel 22, and the third subpixel 23 can also differ from each other. But embodiments of this disclosure are not limited thereto.

In this embodiment, however, the thicknesses T2a, T2b, and T2c of the bank BK and the thicknesses T1a, T1b, and T1c of the light-emitting layer 5 can be designed to be the same within the same subpixel 21, 22, and 23, and the surface heights of the bank BK and the light-emitting layer 5 within the same subpixel 21, 22, and 23 can be designed to be the same.

According to this embodiment, the performance of the display device can be optimized by finely tuning the microcavity characteristics in each subpixel 21, 22, and 23 through the adjustment of the thicknesses T2a, T2b, and T2c of the bank BK and the thicknesses T1a, T1b, and T1c of the light-emitting layer 5.

Further details are as described above with reference to FIG. 2 and will be omitted hereinafter.

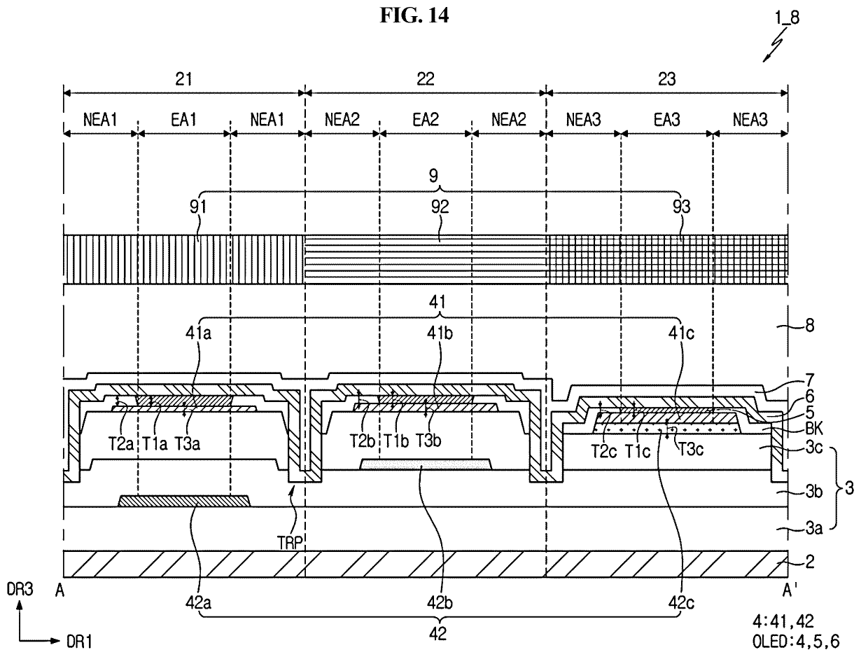

FIG. 14 is a cross-sectional view of a display device according to another embodiment.

Referring to FIG. 14, the display device 1_8 according to this embodiment differs from the display device 1_7 according to FIG. 13 in that the thicknesses T3a, T3b, and T3c of the anode electrodes 41a, 41b, and 41c can be adjusted

More specifically, the thicknesses T3a, T3b, and T3c of the anode electrodes 41a, 41b, and 41c can differ from each other, and the thickness can increase in the order of the first anode electrode 41a, the second anode electrode 41b, and the third anode electrode 41c.

In addition, the thicknesses T2a, T2b, and T2c of the bank BK and the thicknesses T1a, T1b, and T1c of the light-emitting layer 5 can decrease in the order of the first anode electrode 41a, the second anode electrode 41b, and the third anode electrode 41c.

According to this embodiment, the performance of the display device can be optimized by finely tuning the microcavity characteristics in each subpixel 21, 22, and 23 through the adjustment of the thicknesses T3a, T3b, and T3c of the anode electrodes 41a, 41b, and 41c, as well as the thicknesses T2a, T2b, and T2c of the bank BK and the thicknesses T1a, T1b, and T1c of the light-emitting layer 5.

The display device according to various embodiments of this disclosure can be described as follows.

A display device according to various embodiments of this disclosure includes a substrate defining a subpixel including an emissive area and a non-emissive area surrounding the emissive area, a reflective electrode on the substrate, an anode electrode on the reflective electrode in the emissive area, a bank on the anode electrode in the non-emissive area, and a first emissive layer on the anode electrode in the emissive area, wherein a surface height of the bank is equal to a surface height of the first emissive layer.

In the display device according to various embodiments of this disclosure, a thickness of the bank can be equal to a thickness of the first emissive layer.

In the display device according to various embodiments of this disclosure, an outer surface of the bank can have hydrophobicity.

The display device according to various embodiments of this disclosure can further include a second emissive layer on the first emissive layer, wherein the second emissive layer can be disposed across the emissive area and the non-emissive area, and a surface of the second emissive layer can be flat.

In the display device according to various embodiments of this disclosure, the second emissive layer can have a void in the non-emissive area.

The display device according to various embodiments of this disclosure can further include at least one insulating layer between the reflective electrode and the anode electrode, wherein the insulating layer can include a trench portion recessed in a thickness direction in the non-emissive area.

In the display device according to various embodiments of this disclosure, the trench portion can include a residue portion disposed therein, the residue portion including the same material as the first emissive layer.

In the display device according to various embodiments of this disclosure, the subpixel can include a first subpixel, a second subpixel, and a third subpixel, and a thickness of the first emissive layer of the first subpixel, a thickness of the first emissive layer of the second subpixel, and a thickness of the first emissive layer of the third subpixel can be different from one another.

In the display device according to various embodiments of this disclosure, a thickness of the bank of the first subpixel, a thickness of the bank of the second subpixel, and a thickness of the bank of the third subpixel can be different from one another.

In the display device according to various embodiments of this disclosure, the subpixel includes a first subpixel, a second subpixel, and a third subpixel, and a thickness of the anode electrode of the first subpixel, a thickness of the anode electrode of the second subpixel, and a thickness of the anode electrode of the third subpixel can be different from one another.

A display device according to various embodiments of this disclosure includes a substrate defining a subpixel including an emissive area and a non-emissive area surrounding the emissive area, a reflective electrode on the substrate, an anode electrode on the reflective electrode in the emissive area, a bank on the anode electrode in the non-emissive area, and an emissive layer on the anode electrode in the emissive area, wherein a surface height of the bank is equal to a surface height of the anode electrode in the emissive area.

The display device according to various embodiments of this disclosure can include at least one insulating layer between the reflective electrode and the anode electrode, wherein the insulating layer can include a trench portion recessed in a thickness direction in the non-emissive area.

In the display device according to various embodiments of this disclosure, the bank need not overlap the trench portion.

In the display device according to various embodiments of this disclosure, the bank can extend into the trench portion, and the emissive layer can directly contact a side surface of the bank in the trench portion.

A display device according to various embodiments of this disclosure includes a substrate defining a subpixel including an emissive area and a non-emissive area surrounding the emissive area, a reflective electrode on the substrate, at least one insulating layer on the reflective electrode, the at least one insulating layer including a trench portion recessed in a thickness direction in the non-emissive area, an anode electrode on the at least one insulating layer, a bank on the anode electrode in the non-emissive area, and an emissive layer on the anode electrode in the emissive area, wherein a surface height of the bank is equal to a surface height of the anode electrode in the emissive area.

The display device according to various embodiments of this disclosure further includes a cathode electrode on the emissive layer, a capping layer on the cathode electrode, and a step compensation portion on the capping layer in the non-emissive area.

In the display device according to various embodiments of this disclosure, the step compensation portion can include an organic material.

In the display device according to various embodiments of this disclosure, in the non-emissive area, a surface height of the step compensation portion can be equal to a surface height of the capping layer.

The embodiments are advantageous for improving the color deviation of light emitted through a bank in a non-emissive area by designing the surface height of the light-emitting layer in both the emissive area and the non-emissive area to be identical.

The embodiments are advantageous for satisfying microcavity characteristics by adjusting the thickness of the light-emitting layer and the bank.

The embodiments are advantageous for satisfying microcavity characteristics by adjusting the thickness of the anode electrode.

The embodiments are advantageous for improving the seam of the encapsulation layer by minimizing the step difference at the lower part of the encapsulation layer in the non-emissive area.

The embodiments are advantageous for providing a display device with high color reproducibility by reducing the occurrence of color deviation in the non-emissive area.

However, the effects achievable through this disclosure are not limited to the aforementioned, and additional effects not explicitly described herein can be readily understood by those skilled in the art based on the disclosure.

Although the embodiments have been described with reference to the attached drawings, it will be understood by those skilled in the art that the described technical configurations can be implemented in other specific forms without altering the technical essence or essential features. Therefore, it should be understood that the embodiments described above are example and not limited in all respects. Moreover, the scope of the embodiments is determined by the claims that follow, rather than by the detailed description. Any modifications or variations derived from the meaning, scope, and equivalent concepts of the patent claims are to be considered as falling within the scope of the embodiments.

### DESCRIPTION OF REFERENCE NUMERALS

1: display device
2: substrate
3: insulating layer
4: first electrode
5: common light-emitting layer
6: cathode electrode
7: capping layer
8: encapsulation layer
9: color filter layer
BK: bank

What is claimed is:

1. A display device comprising:
a substrate including a subpixel, the subpixel comprising an emissive area and a non-emissive area surrounding the emissive area;
a reflective electrode on the substrate;
an anode electrode on the reflective electrode in the emissive area;
a bank on the anode electrode in the non-emissive area; and
a first emissive layer on the anode electrode in the emissive area,
wherein a surface height of the bank is equal to a surface height of the first emissive layer in the subpixel.

2. The display device of claim 1, wherein a thickness of the bank is equal to a thickness of the first emissive layer in the subpixel.

3. The display device of claim 1, wherein an outer surface of the bank has hydrophobicity.

4. The display device of claim 1, further comprising a second emissive layer on the first emissive layer,
wherein the second emissive layer is disposed across the emissive area and the non-emissive area in the subpixel, and a surface of the second emissive layer is flat.

5. The display device of claim 4, wherein the second emissive layer has a void in the non-emissive area of the subpixel.

6. The display device of claim 1, further comprising at least one insulating layer between the reflective electrode and the anode electrode,
wherein the at least one insulating layer comprises a trench portion recessed in the non-emissive area in a thickness direction of the at least one insulating layer.

7. The display device of claim 6, wherein the trench portion comprises a residue portion disposed in the trench portion, the residue portion including the same material as the first emissive layer.

8. The display device of claim 1, wherein the subpixel comprises a first subpixel, a second subpixel, and a third subpixel, and a thickness of the first emissive layer of the first subpixel, a thickness of the first emissive layer of the second subpixel, and a thickness of the first emissive layer of the third subpixel are different from one another.

9. The display device of claim 8, wherein a thickness of the bank of the first subpixel, a thickness of the bank of the second subpixel, and a thickness of the bank of the third subpixel are different from one another.

10. The display device of claim 1, wherein the subpixel comprises a first subpixel, a second subpixel, and a third subpixel, and a thickness of the anode electrode of the first subpixel, a thickness of the anode electrode of the second subpixel, and a thickness of the anode electrode of the third subpixel are different from one another.

11. The display device of claim 6, wherein the bank includes a first portion on the anode electrode and a second portion on the at least one insulating layer, and
wherein a thickness of the first portion and a thickness of the second portion are different in the subpixel

12. The display device of claim 1, wherein a thickness of the bank is equal to combined thicknesses of the first emissive layer and the anode electrode in the subpixel.

13. The display device of claim 6, wherein the trench portion is located between adjacent subpixels including the subpixel, and
wherein the bank is connected between the adjacent subpixels.

14. A display device comprising:
a substrate including a subpixel, the subpixel comprising an emissive area and a non-emissive area surrounding the emissive area;
a reflective electrode on the substrate;
an anode electrode on the reflective electrode in the emissive area;
a bank on the anode electrode in the non-emissive area; and
an emissive layer on the anode electrode in the emissive area,
wherein a surface height of the bank is equal to a surface height of the anode electrode in the emissive area of the subpixel.

15. The display device of claim 14, further comprising at least one insulating layer between the reflective electrode and the anode electrode,
wherein the at least one insulating layer comprises a trench portion recessed in the non-emissive area in a thickness direction of the at least one insulating layer.

16. The display device of claim 15, wherein the bank does not overlap the trench portion.

17. The display device of claim 15, wherein the bank extends into the trench portion, and the emissive layer directly contacts a side surface of the bank in the trench portion.

18. A display device comprising:
a substrate including a subpixel, the subpixel comprising an emissive area and a non-emissive area surrounding the emissive area;
a reflective electrode on the substrate;
at least one insulating layer on the reflective electrode, the at least one insulating layer comprising a trench portion recessed in the non-emissive area in a thickness direction of the at least one insulating layer;
an anode electrode on the at least one insulating layer;
a bank on the anode electrode in the non-emissive area;
an emissive layer on the anode electrode in the emissive area;
a cathode electrode on the emissive layer;
a capping layer on the cathode electrode; and
a step compensation portion on the capping layer in the non-emissive area.

19. The display device of claim 18, wherein the step compensation portion comprises an organic material.

20. The display device of claim 18, wherein, in the non-emissive area, a surface height of the step compensation portion is equal to a surface height of the capping layer in the subpixel.
